(19) United States
(12) Patent Application Publication
(10) Pub. No.: US 2013/0167926 A1
(43) Pub. Date: Jul. 4, 2013

(54) Electronic Device Module Comprising Ethylene-Alpha Olefin Tapered Block Copolymers and Optional Vinyl Silane

(71) Applicants: Debra H. Niemann, Lake Jackson, TX (US); John A. Naumovitz, Midland, MI (US); Rajen M. Patel, Lake Jackson, TX (US); Shaofu Wu, Sugar Land, TX (US)

(72) Inventors: Debra H. Niemann, Lake Jackson, TX (US); John A. Naumovitz, Midland, MI (US); Rajen M. Patel, Lake Jackson, TX (US); Shaofu Wu, Sugar Land, TX (US)

(21) Appl. No.: 13/821,272

(22) PCT Filed: Sep. 2, 2011
(86) PCT No.: PCT/US2011/050330

§ 371 Date: Mar. 7, 2013

Related U.S. Application Data
(60) Provisional application No. 61/384,872, filed on Sep. 21, 2010.

(51) Int. Cl. H01L 31/048

(52) U.S. Cl. CPC H01L 31/0481
USPC 136/259; 438/64

(57) ABSTRACT

An electronic device module such as a solar cell is described. The electronic device module is made using a polymeric material in intimate contact with at least one surface of the electronic device, the polymeric material comprising a tapered block copolymer comprising an A block, and a B block.

### CROSS REFERENCE TO RELATED APPLICATION

This application claims priority to U.S. Provisional Application No. 61/384,872, filed Sep. 21, 2010. For purposes of United States patent practice, the contents of this provisional application are herein incorporated by reference.

### FIELD OF THE INVENTION

This invention relates to electronic device modules. In one aspect, the invention relates to electronic device modules comprising an electronic device, e.g., a solar or photovoltaic (PV) cell, and a protective polymeric material while in another aspect, the invention relates to electronic device modules in which the protective polymeric material is an ethylene-based polymer composition characterized by a block polymer (as described in U.S. Pat. No. 5,798,420) having an A block and a B block, and if a diene is present in the A block, a nodular polymer formed by coupling two or more block polymers.

### BACKGROUND OF THE INVENTION

Polymeric materials are commonly used in the manufacture of modules comprising one or more electronic devices including, but not limited to, solar cells (also known as photovoltaic cells), liquid crystal panels, electro-luminescent devices and plasma display units. The modules often comprise an electronic device in combination with one or more substrates, e.g., one or more glass cover sheets, often positioned between two substrates in which one or both of the substrates comprise glass, metal, plastic, rubber or another material. The polymeric materials are typically used as the encapsulant or sealant for the module or depending upon the design of the module, as a skin layer component of the module, e.g., a backskin in a solar cell module. Typical polymeric materials for these purposes include silicone resins, epoxy resins, polyvinyl butyral resins, cellulose acetate, ethylene-vinyl acetate copolymer (EVA) and ionomers.

### SUMMARY OF THE INVENTION

In one embodiment the invention is an electronic device module comprising:
A. At least one electronic device, and
B. A polymeric material in intimate contact with at least one surface of the electronic device, the polymeric material comprising an ethylene-based block copolymer having an A block and a B block characterized by a nodular polymer formed by coupling two or more block copolymers.
   The nodular polymer may optionally contain a coupling agent Y.

In one embodiment the invention is a method of manufacturing an electronic device module, the method comprising the step of contacting at least one surface of an electronic device with a polymeric material comprising an ethylene-based block copolymer having an A block and a B block characterized by a nodular polymer formed by coupling two or more block copolymers. The nodular polymer may optionally contain a coupling agent Y.

“A” denotes a block comprising polyethylene, and optionally an alpha-olefin comonomer not exceeding 5 mole percent based on the total moles of monomers in the A block, and further optionally containing up to about 10 mole percent of a non-conjugated diene. The diene is present at this mole percent based on the total A B block copolymer.

The A block is present in the block copolymer preferably in the range of 5 to 90 weight percent based on the total weight of the block copolymer, more preferably in the range of 10 to 60 weight percent, most preferably in the range of 20 to 50 weight percent.

“B” denotes a block comprising ethylene and α-olefin copolymer. The B block comprises one or more segments. If there is one segment in the B block, it will be an ethylene, α-olefin segment. If there are two or more segments in the B block, the first segment immediately following the junction of the A and B blocks will be an ethylene α-olefin copolymer segment. The tip or end segment will be located in the portion of the B block furthest from the A B junction. If there are two segments, the second or tip segment will be an ethylene alpha-olefin copolymer with an average ethylene content of at least 60 mole percent based on the total moles of the monomers of the tip segment, and which melts in the range of 35° to 130° C., as measured by DSC.

Optionally, the polymeric material comprises a vinyl silane, e.g., vinyl tri-ethoxy silane or vinyl tri-methoxy silane, in an amount of at least 0.1 wt % based on the weight of the copolymer.

Optionally, the polymeric material comprises a free radical initiator, e.g., a peroxide or azo compound, or a photoinitiator, e.g., benzophenone, in an amount of at least 0.05 wt % based on the weight of the copolymer.

Optionally, the polymeric material comprises a co-agent in an amount of at least 0.05 wt % based on the weight of the copolymer.

“In intimate contact” and like terms mean that the polymeric material is in contact with at least one surface of the device or other article in a similar manner as a coating is in contact with a substrate, e.g., little, if any gaps or spaces between the polymeric material and the face of the device and with the material exhibiting good to excellent adhesion to the face of the device. After extrusion or other method of applying the polymeric material to at least one surface of the electronic device, the material typically forms and/or cures to a film that can be either transparent or opaque and either flexible or rigid. If the electronic device is a solar cell or other device that requires unobstructed or minimally obstructed access to sunlight or to allow a user to read information from it, e.g., a plasma display unit, then that part of the material that covers the active or “business” surface of the device is highly transparent.

The module can further comprise one or more other components, such as one or more glass cover sheets, and in these embodiments, the polymeric material usually is located between the electronic device and the glass cover sheet in a sandwich configuration. If the polymeric material is applied as a film to the surface of the glass cover sheet opposite the electronic device, then the surface of the film that is in contact with that surface of the glass cover sheet can be smooth or uneven, e.g., embossed or textured.

Typically, the polymeric material is an ethylene-based polymer. The polymeric material can fully encapsulate the electronic device, or it can be in intimate contact with only a portion of it, e.g., laminated to one face surface of the device. Optionally, the polymeric material can further comprise a scorch inhibitor, and depending upon the application for which the module is intended, the chemical composition of the copolymer and other factors, the copolymer can remain uncrosslinked or be crosslinked. If crosslinked, then it is crosslinked such that it contains less than about 85 percent xylene soluble extractables as measured by ASTM 2765-95.

In one embodiment the invention is the electronic device module as described in the two embodiments above except that the polymeric material in intimate contact with at least one surface of the electronic device is a co-extruded material in which at least one outer skin layer (i) does not contain peroxide for crosslinking, and (ii) is the surface which comes into intimate contact with the module. Typically, this outer skin layer exhibits good adhesion to glass. This outer skin of the co-extruded material can comprise any one of a number of different polymers, but is typically the same polymer as the polymer of the peroxide-containing layer but without the peroxide. This embodiment of the invention allows for the use of higher processing temperatures which, in turn, allows for faster production rates without unwanted gel formation in the encapsulating polymer due to extended contact with the metal surfaces of the processing equipment. In one embodiment the extruded product comprises at least three layers in which the skin layer in contact with the electronic module is without peroxide, and the peroxide-containing layer is a core layer.

In a variant on the method embodiments, the module further comprises at least one translucent cover layer disposed apart from one face surface of the device, and the polymeric material is interposed in a sealing relationship between the electronic device and the cover layer. “In a sealing relationship” and like terms mean that the polymeric material adheres well to both the cover layer and the electronic device, typically to at least one face surface of each, and that it binds the two together with little, if any, gaps or spaces between the two module components (other than any gaps or spaces that may exist between the polymeric material and the cover layer as a result of the polymeric material applied to the cover layer in the form of an embossed or textured film, or the cover layer itself is embossed or textured).

Moreover, in these method embodiments the polymeric material can further comprise a scorch inhibitor, and the method can optionally include a step in which the copolymer is crosslinked, e.g., either contacting the electronic device and/or glass cover sheet with the polymeric material under crosslinking conditions, or exposing the module to crosslinking conditions after the module is formed such that the polyolefin copolymer contains less than 85 percent xylene soluble extractables as measured by ASTM 2765-95. Crosslinking conditions include heat (e.g., a temperature of at least 160° C.), radiation (e.g., at least 15 mega-rad if by E-beam, or 0.05 joules/cm² if by UV light), moisture (e.g., a relative humidity of at least 50%), etc.

In one variant of these method embodiments, the electronic device is encapsulated, i.e., fully engulfed or enclosed, within the polymeric material. In one variant on these embodiments, the glass cover sheet is treated with a silane coupling agent, e.g., γ-amino propyl tri-ethoxy silane. In one variant on these embodiments, the polymeric material further comprises a graft polymer to enhance its adhesive property relative to the one or both of the electronic device and glass cover sheet. Typically the graft polymer is made in situ simply by grafting the polyolefin copolymer with an unsaturated organic compound that contains a carbonyl group, e.g., maleic anhydride.

In one embodiment the invention is an ethylene/non-polar α-olefin polymeric film characterized in that the film has (i) greater than or equal to (≧) 90% transmittance over the wavelength range from 400 to 1100 nanometers (nm), and (ii) a water vapor transmission rate (WVTR) of less than (<)50, preferably <15, grams per square meter per day (g/m²-day) at 38° C. and 100% relative humidity (RH).

Fabricated articles comprising the polymer compositions used in the practice of this invention are also contemplated, especially in the form of at least one film layer. Other embodiments include thermoplastic formulations comprising the polymer compositions and at least one natural or synthetic polymer.

The ethylene-based polymer composition can be at least partially cross-linked (at least 5% (weight) gel).

### BRIEF DESCRIPTION OF THE DRAWINGS

FIG. 1 is a schematic of one embodiment of an electronic device module of this invention, i.e., a rigid photovoltaic (PV) module.

FIG. 2 is a schematic of another embodiment of an electronic device module of this invention, i.e., a flexible PV module.

### DESCRIPTION OF THE PREFERRED EMBODIMENTS

The polyolefin copolymers useful in the practice of this invention comprise a novel block copolymer having an A block and a B block and when a diene is present in the A block, a nodular polymer formed by coupling two or more block copolymers. The nodular polymer may optionally contain a coupling agent Y.

Optionally the B block has an intramolecular composition distribution such that at least two portions of the B block, each portion comprising at least 5 weight percent of the B block, differ in composition by at least 5 weight percent ethylene. The B block is present in the block copolymer in the range of from 10 to 95 weight percent based on the total weight of the block copolymer.

The tip of the B block can comprise up to 50 weight percent of the B block, preferably in the range of from 3 to 20 weight percent, more preferably in the range of from 5 to 15 weight percent, all weight percents of the tip based on the total weight of the B block. The tip segment, when present, is typically the segment furthest from the A B junction.

Y is a coupling agent which has reacted with the residual olefinic functionality in the block polymers and has coupled two or more block polymer molecules.

A is a crystalline block and B has elastomeric segments. B may optionally contain a low level of crystallinity.

### Copolymer Blocks

Block A

Block A comprises polyethylene which optionally may contain up to 10 mole percent of a non-conjugated diene (based on the total moles of the monomers of the A B copolymer). The A block may optionally contain an α-olefin comonomer at a level not exceeding 5 mole percent based on the total moles of the monomers of the A block. If block A contains a non-conjugated diene it will be present in the A block preferably in the range of 0.01 to 5 mole percent, more preferably in the range of 0.03 to 2 mole percent, most preferably in the range of 0.05 to 1 mole percent based on the total moles of the monomers of the A B block copolymer. The A block has a Tₘ of at least 110° C., preferably at least 120° C.

Block B

Block B is an elastomer that comprises an ethylene and α-olefin copolymer. Block B optionally has an intramolecular-compositional distribution such that at least two portions of the B block, each of said portions comprising at least 5 weight percent of said B block, differ in composition by at least 5 weight percent ethylene. Intramolecular-compositional distribution is the compositional variation, in terms of ethylene, along the polymer chain or block. It is expressed as the minimum difference in average ethylene composition in weight percent of ethylene that exists between two portions of a single block, each portion comprising at least 5 weight percent of the block. Intramolecular-compositional distribution is determined using the procedures disclosed in U.S. Pat. No. 4,959,436. The B block comprises 95 to 10 weight percent of the total weight of the block copolymer, preferably 90 to 40 weight percent; more preferably 80 to 50 weight percent.

The tip of the B block can comprise up to 50 weight percent of the B block, preferably in the range of 3 to 20 weight percent, more preferably in the range of 5 to 15 weight percent, all weight percents of the tip based on the total weight of the B block. The tip segment, when present, is typically the segment furthest from the A B junction.

The B block can comprise an average ethylene content in the range of 20 to 90 mole percent, preferably in the range of 30 to 85 mole percent, and most preferably in the range of 50 to 80 mole percent based on the total moles of the monomers of the B block.

The polyolefin copolymers useful in the practice of this invention are further characterized in that they have a number average molecular weight of between 750 and 20,000,000 and have a molecular weight distribution characterized by M_{w}/Mₙ ratio of less than 2.5. The block copolymers have an n-hexane soluble portion, at 22° C. not exceeding 50 weight percent, preferably not exceeding 40 weight percent, and more preferably not exceeding 30 weight percent, based on the total weight of the block copolymer. The polyolefin copolymers useful in the practice of this invention are further characterized by a relatively small amount of polymer chains in the final product that contain only an A block or only a B block. The presence of such materials could detract from overall product properties. A typical characteristic of the preferred polyolefin copolymer useful in the practice of this invention is that the block copolymer contains at least 50% (weight) of the desired A B structure as polymerized. Product purification is not necessary to obtain good properties.

Monomers

The polyolefin copolymers useful in the practice of this invention contain alpha-olefins having from 3 to 8 carbon atoms, e.g. propylene, butene-1, pentene-1, etc. Alpha-olefins of 3 to 6 carbon atoms are preferred due to economic considerations. The most preferred α-olefin is propylene.

The polyolefin copolymers useful in the practice of this invention may also contain non-conjugated dienes such as:

(a) straight chain acyclic dienes such as: 1,4-hexadiene; 1,6-octadiene;

(b) branched chain acyclic dienes such as: 5-methyl-1,4-hexadiene; 3,7-dimethyl-1,6-octadiene; 3,7-dimethyl-1,7-dioctadiene; and the mixed isomers of dihydromyrcene and dihydro-ocinene;

(c) single ring dienes such as: 1,4-cyclohexadiene; 1,5-cyclooctadiene; and 1,5-cyclododecadiene;

(d) multi-ring fixed and fused ring dienes such as: tetrahydroindene; methyltetra-hydroindene; dicyclopentadiene; bicyclo-(2,2,1)-hepta-2,5-diene; alkenyl, alkylidene, cycloalkenyl and cycloalkylidene norbornenes such as 5-methylene-2-norbornene (MNB), 5-ethylidene-2-norbornene (ENB), 5-propenyl-2-norbornene, 5-(4-cyclopentenyl)-2-norbornene, 5-cyclohexylidene-2-norbornene, vinyl norbornene, and norbornadiene.

Of the non-conjugated dienes useful in the practice of the invention, dienes containing at least one of the double bonds in a strained ring are preferred. The most preferred dienes are 5-ethylidene-2-norbonene and vinyl-norbornene. Conjugated dienes are also contemplated.

Polymerization

The polyolefin copolymers useful in the practice of this invention are prepared by polymerization in a mix-free reactor similar to that taught in U.S. Pat. No. 4,959,436.

Coupling the Polymers

The polyolefin copolymers useful in the practice of this invention may incorporate a diene. The residual olefinic functionality in diene containing block polymers can be reacted with coupling agents to produce nodular polymers.

Suitable coupling reagents and coupling techniques are described in U.S. Pat. No. 4,882. Coupling can take place either within the polymerization reactor or in a post-polymerization reaction. With the diene in the A block, the polyethylene segment containing the diene is in a central polyethylene nodule with EP block extending outwards.

There are various coupling agents that are capable of reacting with the residual unsaturation in the polymer chains to cause coupling of two or more block polymer molecules. Coupling may be carried out with cationic catalysts such as Lewis acids. In one embodiment the coupling agent may be a free radical catalyst. The free radical catalyst may be a peroxide or an azo compound. In one embodiment the coupling agent may be selected from the group consisting of sulfur dichloride, disulfenyl halides, borane, dithoalkanes, other sulfur and accelerated sulfur curatives and mixtures thereof, such as mercaptobenzothiozole, tetramethylthiuram disulfide, and butyl zymate. Resins and other reagents may also be employed for coupling. For example alkyl phenol formaldehyde mixtures will couple olefins in certain cases with catalysts such as ZnCl₂, N-bromosuccinimide or diphenylbromomethane. Also contemplated as a coupling mechanism is the use of irradiation or electron beams.

Blends of any of the above olefinic interpolymers can also be used in this invention, and the polyolefin interpolymers can be blended or diluted with one or more other polymers to the extent that the polymers are (i) miscible with one another, (ii) the other polymers have little, if any, impact on the desirable properties of the polyolefin interpolymer, e.g., optics and low modulus, and (iii) the polyolefin interpolymers of this invention constitute at least 70, preferably at least 75 and more preferably at least 80, weight percent of the blend. Although not favored, EVA copolymer can be one of the diluting polymers.

Typically the polyolefin copolymers used in the practice of this invention also have a melt index (MI as measured by the procedure of ASTM D-1238 (190C/2.16 kg)) of less than 100, preferably less than 75, more preferably less than 50 and even more preferably less than 35, g/10 minutes. The typical minimum MI is 1, and more typically it is 5.

Due to the low density and modulus of the polyolefin copolymers used in the practice of this invention, these copolymers are typically cured or crosslinked at the time of contact or after, usually shortly after, the module has been constructed. Crosslinking is important to the performance of the copolymer in its function to protect the electronic device from the environment. Specifically, crosslinking enhances the thermal creep resistance of the copolymer and durability of the module in terms of heat, impact and solvent resistance. Crosslinking can be effected by any one of a number of different methods, e.g., by the use of thermally activated initiators, e.g., peroxides and azo compounds; photoinitiators, e.g., benzophenone; radiation techniques including sunlight, UV light, E-beam and x-ray; vinyl silane, e.g., vinyl tri-ethoxy or vinyl tri-methoxy silane; and moisture cure.

The free radical initiators used in the practice of this invention include any thermally activated compound that is relatively unstable and easily breaks into at least two radicals. Representative of this class of compounds are the peroxides, particularly the organic peroxides, and the azo initiators. Of the free radical initiators used as crosslinking agents, the dialkyl peroxides and diperoxyketal initiators are preferred. These compounds are described in the Encyclopedia of Chemical Technology, 3rd edition, Vol. 17, pp 27-90. (1982).

The amount of peroxide or azo initiator present in the crosslinkable compositions of this invention can vary widely, but the minimum amount is that sufficient to afford the desired range of crosslinking. The minimum amount of initiator is typically at least 0.05, preferably at least 0.1 and more preferably at least 0.25, wt % based upon the weight of the polymer or polymers to be crosslinked. The maximum amount of initiator used in these compositions can vary widely, and it is typically determined by such factors as cost, efficiency and degree of desired crosslinking desired. The maximum amount is typically less than 10, preferably less than and more preferably less than 3, wt % based upon the weight of the polymer or polymers to be crosslinked.

Free radical crosslinking initiation via electromagnetic radiation, e.g., sunlight, ultraviolet (UV) light, infrared (IR) radiation, electron beam, beta-ray, gamma-ray, x-ray and neutron rays, may also be employed. Radiation is believed to affect crosslinking by generating polymer radicals, which may combine and crosslink. The Handbook of Polymer Foams and Technology, supra, at pp. 198-204, provides additional teachings. Elemental sulfur may be used as a crosslinking agent for diene containing polymers such as EPDM and polybutadiene. The amount of radiation used to cure the copolymer will vary with the chemical composition of the copolymer, the composition and amount of initiator, if any, the nature of the radiation, and the like, but a typical amount of UV light is at least t 0.05, more typically at 0.1 and even more typically at least 0.5, Joules/cm², and a typical amount of E-beam radiation is at least 0.5, more typically at least 1 and even more typically at least 1.5, megarads.

If sunlight or UV light is used to effect cure or crosslinking, then typically and preferably one or more photoinitiators are employed. Such photoinitiators include organic carbonyl compounds such as such as benzophenone, benzanthrone, benzoin and alkyl ethers thereof, 2,2-diethoxyacetophenone, 2,2-dimethoxy, 2 phenylacetophenone, p-phenoxy dichloroacetophenone, 2-hydroxycyclohexylphenone, 2-hydroxyisopropylphenone, and 1-phenylpropanedione-2-(ethoxy carboxyl) oxime. These initiators are used in known manners and in known quantities, e.g., typically at least 0.05, more typically at least 0.1 and even more typically 0.5, wt % based on the weight of the copolymer.

If moisture, i.e., water, is used to effect cure or crosslinking, then typically and preferably one or more hydrolysis/condensation catalysts are employed. Such catalysts include Lewis acids such as dibutyltin dilaurate, dioctyltin dilaurate, stannous octonoate, and hydrogen sulfonates such as sulfonic acid.

Free radical crosslinking coagents, i.e. promoters or co-initiators, include multifunctional vinyl monomers and polymers, triallyl cyanurate and trimethylolpropane trimethacrylate, divinyl benzene, acrylates and methacrylates of polyols, allyl alcohol derivatives, and low molecular weight polybutadiene. Sulfur crosslinking promoters include benzothiazyl disulfide, 2-mercaptobenzothiazole, copper dimethyldithiocarbamate, dipentamethylene thiuram tetrasulfide, tetrabutylthiuram disulfide, tetramethylthiuram disulfide and tetramethylthiuram monosulfide.

These coagents are used in known amounts and known ways. The minimum amount of coagent is typically at least 0.05, preferably at least 0.1 and more preferably at least 0.5, wt % based upon the weight of the polymer or polymers to be crosslinked. The maximum amount of coagent used in these compositions can vary widely, and it is typically determined by such factors as cost, efficiency and degree of desired crosslinking desired. The maximum amount is typically less than 10, preferably less than 5 and more preferably less than 3, wt % based upon the weight of the polymer or polymers to be crosslinked.

One difficulty in using thermally activated free radical initiators to promote crosslinking, i.e., curing, of thermoplastic materials is that they may initiate premature crosslinking, i.e., scorch, during compounding and/or processing prior to the actual phase in the overall process in which curing is desired. One method of minimizing scorch is the incorporation of scorch inhibitors into the compositions. One commonly used scorch inhibitor for use in free radical, particularly peroxide, initiator-containing compositions is 4-hydroxy-2,2,6,6-tetramethylpiperidin-1-oxyl also known as nitroxyl 2, or NR 1, or 4-oxypiperidol, or tanol, or tempol, or tmpn, or probably most commonly, 4-hydroxy-TEMPO or even more simply, h-TEMPO. The addition of 4-hydroxy-TEMPO minimizes scorch by “quenching” free radical crosslinking of the crosslinkable polymer at melt processing temperatures.

The preferred amount of scorch inhibitor used in the compositions of this invention will vary with the amount and nature of the other components of the composition, particularly the free radical initiator, but typically the minimum amount of scorch inhibitor used in a system of polyolefin copolymer with 1.7 weight percent (wt %) peroxide is at least 0.01, preferably at least 0.05, more preferably at least 0.1 and most preferably at least 0.15, wt % based on the weight of the polymer. The maximum amount of scorch inhibitor can vary widely, and it is more a function of cost and efficiency than anything else. The typical maximum amount of scorch inhibitor used in a system of polyolefin copolymer with 1.7 wt % peroxide does not exceed 2, preferably does not exceed 1.5 and more preferably does not exceed 1, wt % based on the weight of the copolymer.

Any silane that will effectively graft to and crosslink the polyolefin copolymer can be used in the practice of this invention. Suitable silanes include unsaturated silanes that comprise an ethylenically unsaturated hydrocarbyl group, such as a vinyl, allyl, isopropenyl, butenyl, cyclohexenyl or γ-(meth)acryloxy allyl group, and a hydrolyzable group, such as, for example, a hydrocarbyloxy, hydrocarbonyloxy, or hydrocarbylamino group. Examples of hydrolyzable groups include methoxy, ethoxy, formyloxy, acetoxy, proprionyloxy, and alkyl or arylamino groups. Preferred silanes are the unsaturated alkoxy silanes which can be grafted onto the polymer. These silanes and their method of preparation are more fully described in U.S. Pat. No. 5,266,627. Vinyl trimethoxy silane, vinyl triethoxy silane, γ-(meth)acryloxy propyl trimethoxy silane and mixtures of these silanes are the preferred silane crosslinkers for is use in this invention. If filler is present, then preferably the crosslinker includes vinyl triethoxy silane.

The amount of silane crosslinker used in the practice of this invention can vary widely depending upon the nature of the polyolefin copolymer, the silane, the processing conditions, the grafting efficiency, the ultimate application, and similar factors, but typically at least 0.5, preferably at least 0.7, parts per hundred resin wt % is used based on the weight of the copolymer. Considerations of convenience and economy are usually the two principal limitations on the maximum amount of silane crosslinker used in the practice of this invention, and typically the maximum amount of silane crosslinker does not exceed 5, preferably it does not exceed 2, wt % based on the weight of the copolymer.

The silane crosslinker is grafted to the polyolefin copolymer by any conventional method, typically in the presence of a free radical initiator e.g. peroxides and azo compounds, or by ionizing radiation, etc. Organic initiators are preferred, such as any of those described above, e.g., the peroxide and azo initiators. The amount of initiator can vary, but it is typically present in the amounts described above for the crosslinking of the polyolefin copolymer.

While any conventional method can be used to graft the silane crosslinker to the polyolefin copolymer, one preferred method is blending the two with the initiator in the first stage of a reactor extruder, such as a Buss kneader. The grafting conditions can vary, but the melt temperatures are typically between 160 and 260° C., preferably between 190 and 230° C., depending upon the residence time and the half life of the initiator.

In another embodiment of the invention, the polymeric material further comprises a graft polymer to enhance the adhesion to one or more glass cover sheets to the extent that these sheets are components of the electronic device module. While the graft polymer can be any graft polymer compatible with the polyolefin copolymer of the polymeric material and which does not significantly compromise the performance of the polyolefin copolymer as a component of the module, typically the graft polymer is a graft polyolefin polymer and more typically, a graft polyolefin copolymer that is of the same composition as the polyolefin copolymer of the polymeric material. This graft additive is typically made in situ simply by subjecting the polyolefin copolymer to grafting reagents and grafting conditions such that at least a portion of the polyolefin copolymer is grafted with the grafting material.

Any unsaturated organic compound containing at least one ethylenic unsaturation (e.g., at least one double bond), at least one carbonyl group (—C═O), and that will graft to a polymer, particularly a polyolefin polymer and more particularly to a polyolefin copolymer, can be used as the grafting material in this embodiment of the invention. Representative of compounds that contain at least one carbonyl group are the carboxylic acids, anhydrides, esters and their salts, both metallic and nonmetallic. Preferably, the organic compound contains ethylenic unsaturation conjugated with a carbonyl group. Representative compounds include maleic, fumaric, acrylic, methacrylic, itaconic, crotonic, α-methyl crotonic, and cinnamic acid and their anhydride, ester and salt derivatives, if any. Maleic anhydride is the preferred unsaturated organic compound containing at least one ethylenic unsaturation and at least one carbonyl group.

The unsaturated organic compound content of the graft polymer is at least 0.01 wt %, and preferably at least 0.05 wt %, based on the combined weight of the polymer and the organic compound. The maximum amount of unsaturated organic compound content can vary to convenience, but typically it does not exceed 10 wt %, preferably it does not exceed 5 wt %, and more preferably it does not exceed 2 wt %.

The unsaturated organic compound can be grafted to the polymer by any known technique, such as those taught in U.S. Pat. Nos. 3,236,917 and 5,194,509. For example, in the '917 patent the polymer is introduced into a two-roll mixer and mixed at a temperature of 60° C. The unsaturated organic compound is then added along with a free radical initiator, such as, for example, benzoyl peroxide, and the components are mixed at 30° C. until the grafting is completed. In the '509 patent, the procedure is similar except that the reaction temperature is higher, e.g., 210 to 300° C., and a free radical initiator is not used or is used at a reduced concentration.

An alternative and preferred method of grafting is taught in U.S. Pat. No. 4,950,541 by using a twin-screw devolatilizing extruder as the mixing apparatus. The polymer and unsaturated organic compound are mixed and reacted within the extruder at temperatures at which the reactants are molten and in the presence of a free radical initiator. Preferably, the unsaturated organic compound is injected into a zone maintained under pressure within the extruder.

The polymeric materials of this invention can comprise other additives as well. For example, such other additives include UV-stabilizers and processing stabilizers such as trivalent phosphorus compounds. The UV-stabilizers are useful in lowering the wavelength of electromagnetic radiation that can be absorbed by a PV module (e.g., to less than 360 nm), and include hindered phenols such as Cyasorb UV2908 and hindered amines such as Cyasorb UV 3529, Hostavin N30, Univil 4050, Univin 5050, Chimassorb UV 119, Chimassorb 944 LD, Tinuvin 622 LD and the like. The phosphorus compounds include phosphonites (PEPQ) and phosphites (Weston 399, TNPP, P-168 and Doverphos 9228). The amount of UV-stabilizer is typically from 0.1 to 0.8%, and preferably from 0.2 to 0.5%. The amount of processing stabilizer is typically from 0.02 to 0.5%, and preferably from 0.05 to 0.15%.

Still other additives include, but are not limited to, antioxidants (e.g., hindered phenolics (e.g., Irganox® 1010 made by Ciba Geigy Corp.), cling additives, e.g., PIB, anti-blocks, anti-slips, pigments, anti-stats, and fillers (clear if transparency is important to the application). In-process additives, e.g. calcium stearate, water, etc., may also be used. These and other potential additives are used in the manner and amount as is commonly known in the art.

The polymeric materials of this invention are used to construct electronic device modules in the same manner and using the same amounts as the encapsulant materials known in the art, e.g., such as those taught in U.S. Pat. No. 6,586,271, US Patent Application Publication US2001/0045229 A1, WO 99/05206 and WO 99/04971. These materials can be used as “skins” for the electronic device, i.e., applied to one or both face surfaces of the device, or as an encapsulant in which the device is totally enclosed within the material. Typically, the polymeric material is applied to the device by one or more lamination techniques in which a layer of film formed from the polymeric material is applied first to one face surface of the device, and then to the other face surface of the device. In an alternative embodiment, the polymeric material can be extruded in molten form onto the device and allowed to congeal on the device. The polymeric materials of this invention exhibit good adhesion for the face surfaces of the device.

In one embodiment, the electronic device module comprises (i) at least one electronic device, typically a plurality of such devices arrayed in a linear or planar pattern, (ii) at least one glass cover sheet, typically a glass cover sheet over both face surfaces of the device, and (iii) at least one polymeric material. The polymeric material is typically disposed between the glass cover sheet and the device, and the polymeric material exhibits good adhesion to both the device and the sheet. If the device requires access to specific forms of electromagnetic radiation, e.g., sunlight, infrared, ultra-violet, etc., then the polymeric material exhibits good, typically excellent, transparency for that radiation, e.g., transmission rates in excess of 90, preferably in excess of 95 and even more preferably in excess of 97, percent as measured by UV-vis spectroscopy (measuring absorbance in the wavelength range of about 250-1200 nanometers. An alternative measure of transparency is the internal haze method of ASTM D-1003-00. If transparency is not a requirement for operation of the electronic device, then the polymeric material can contain opaque filler and/or pigment.

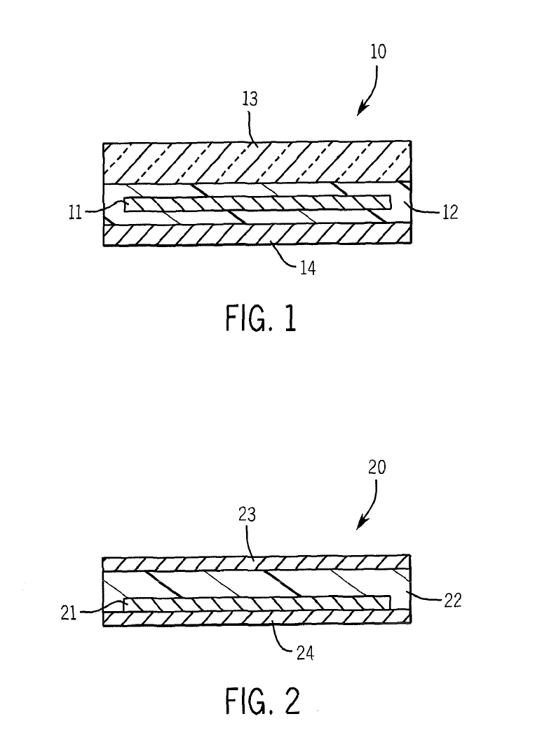

In FIG. 1 rigid PV module 10 comprises photovoltaic cell 11 surrounded or encapsulated by transparent protective layer or encapsulant 12 comprising a polyolefin copolymer used in the practice of this invention. Glass cover sheet 13 covers a front surface of the portion of the transparent protective layer disposed over PV cell 11. Backskin or back sheet 14, e.g., a second glass cover sheet or another substrate of any kind, supports a rear surface of the portion of transparent protective layer 12 disposed on a rear surface of PV cell 11. Backskin layer 14 need not be transparent if the surface of the PV cell to which it is opposed is not reactive to sunlight. In this embodiment, protective layer 12 encapsulates PV cell 11. The thicknesses of these layers, both in an absolute context and relative to one another, are not critical to this invention and as such, can vary widely depending upon the overall design and purpose of the module. Typical thicknesses for protective layer 12 are in the range of about 0.125 to about 2 millimeters (mm), and for the glass cover sheet and backskin layers in the range of about 0.125 to about 1.25 mm. The thickness of the electronic device can also vary widely.

In FIG. 2 flexible PV module 20 comprises thin film photovoltaic 21 over-lain by transparent protective layer or encapsulant 22 comprising a polyolefin copolymer used in the practice of this invention. Glazing/top layer 23 covers a front surface of the portion of the transparent protective layer disposed over thin film PV 21. Flexible backskin or back sheet 24, e.g., a second protective layer or another flexible substrate of any kind, supports the bottom surface of thin film PV 21. Backskin layer 24 need not be transparent if the surface of the thin film cell which it is supporting is not reactive to sunlight. In this embodiment, protective layer 21 does not encapsulate thin film PV 21. The overall thickness of a typical rigid or flexible PV cell module will typically be in the range of about 5 to about 50 mm.

The modules described in FIGS. 1 and 2 can be constructed by any number of different methods, typically a film or sheet co-extrusion method such as blown-film, modified blown-film, calendaring and casting. In one method and referring to FIG. 1, protective layer 14 is formed by first extruding a polyolefin copolymer over and onto the top surface of the PV cell and either simultaneously with or subsequent to the extrusion of this first extrusion, extruding the same, or different, polyolefin copolymer over and onto the back surface of the cell. Once the protective film is attached the PV cell, the glass cover sheet and backskin layer can be attached in any convenient manner, e.g., extrusion, lamination, etc., to the protective layer, with or without an adhesive. Either or both external surfaces, i.e., the surfaces opposite the surfaces in contact with the PV cell, of the protective layer can be embossed or otherwise treated to enhance adhesion to the glass and backskin layers. The module of FIG. 2 can be constructed in a similar manner, except that the backskin layer is attached to the PV cell directly, with or without an adhesive, either prior or subsequent to the attachment of the protective layer to the PV cell.

The numerical ranges in this disclosure are approximate, and thus may include values outside of the range unless otherwise indicated. Numerical ranges include all values from and including the lower and the upper values, in increments of one unit, provided that there is a separation of at least two units between any lower value and any higher value. As an example, if a compositional, physical or other property, such as, for example, molecular weight, viscosity, melt index, etc., is from 100 to 1,000, it is intended that all individual values, such as 100, 101, 102, etc., and sub ranges, such as 100 to 144, 155 to 170, 197 to 200, etc., are expressly enumerated. For ranges containing values which are less than one or containing fractional numbers greater than one (e.g., 1.1, 1.5, etc.), one unit is considered to be 0.0001, 0.001, 0.01 or 0.1, as appropriate. For ranges containing single digit numbers less than ten (e.g., 1 to 5), one unit is typically considered to be 0.1. These are only examples of what is specifically intended, and all possible combinations of numerical values between the lowest value and the highest value enumerated, are to be considered to be expressly stated in this disclosure.

### SPECIFIC EMBODIMENTS

### Polymerization of Uncoupled Block Polymers

### Example 1

Polymerization is carried out in a 0.793 cm diameter tubular reactor with hexane as the reaction diluent. The reactor contains a series of feed inlets along its length. In this example, A B block polymers are formed. The A block is polyethylene (PE) and in runs 1A and 1B the B block is an ethylene/propylene copolymer (EP). These polymers are produced using VCl₄ catalyst and Al₂Et₃Cl₃ (EASC) co-catalyst. The catalyst and co-catalyst are fed into a mixing tee as dilute solutions in hexane at a temperature of 10° C. After mixing, the combined catalyst components flow through a tube with a residence time of 10 seconds at 10° C. before entering the reactor. The monomer feed to the reactor inlet is a solution of ethylene in hexane at 20° C. which is mixed with the catalyst stream to start the polymerization. The reactor is operated adiabatically so that temperature increases along its length.

After a residence time of 0.024 minutes, during which the block A (polyethylene) is formed, a feed of ethylene and propylene dissolved in hexane is added via a side stream injection point to begin polymerization of the B block. Two more ethylene-propylene side feeds are added at residence times of 0.064 and 0.1 minutes to increase the length of the B block. The polymerization is quenched with isopropanol at the end of the reactor. The final reaction temperature is 22° C.

In Examples 1A and 1B no diene is used and the polymerization is quenched at 0.14 min. The reaction conditions of polymerizations 1A and 1B are shown in Table 1.

### Runs 1A and 1B

A number of polymerization experiments are carried out at the conditions used in runs 1A and 1B, but with a polymerization quench injected into the reactor at a residence time of 0.024 min. so that only polyethylene is produced. From the amount of polymer collected in a known period of time, it is determined that close to 100% of the ethylene fed to the reactor in the main flow reacted to form polyethylene. Thus in Examples 1A and 1B, the rate at which the polyethylene A block is produced is equal to the feed rate of ethylene in the main flow. The rate at which the elastomeric B block is produced can be found by subtracting the A block production rate from the measured total polymerization rate. The percentages of A and B block in the polymer are then calculated by dividing the respective polymerization rates of these blocks by the total polymerization rate. The average ethylene content of the polymer is equal to the ethylene content of the A block, which is 100%, times the fraction of the A block in the polymer, plus the ethylene content of the B block times the fraction of B block in the polymer. Thus the ethylene content of the B block can be calculated from the measured average ethylene content of the whole polymer and the polymerization rates from the equation:

Ethylene content of B block,weight percent=(average polymer % ethylene content−100×weight fraction of A block in the total polymer)/weight fraction of B block in the total polymer(all terms are in weight units).

The ethylene content of the entire polymer is determined by infrared spectroscopy using the calibration described in I. J. Gardner, C. Cozewith, and G. Ver Strate, Rubber Chemistry and Technology, vol. 44, 1015, 1971.

The calculated polymer composition is shown in Table 2 along with other measurements of the polymer structure (GPC and DSC). Of particular note is the narrow MWD of the polymers.

Tensile properties of the polymers produced are determined in the following manner. A sheet of polymer 15×15×0.2 cm is prepared by compression molding for 15 minutes at 150° C. An aluminum mold is used with Teflon® coated aluminum foil used as a release agent. Dumbbell-type specimens are die cut from the sheet. These specimens in turn are strained in tension at a crosshead speed of 12.5 cm/min. Initial jaw separation is 5 cm. with about 3.3 cm of the specimen undergoing most of the deformation between the fiducial marks. Data are collected at 20° C. Engineering moduli are calculated as force at a given percent elongation divided by the original unstrained specimen cross-sectional area.

Table 3 shows the moduli and tensile strength of the polymer for runs 1A and 1B. The mechanical properties are a function of molecular weight and the polyethylene block content. The modulus of the polymer containing the larger amount of PE block (1A) are slightly higher than that with a somewhat lower polyethylene block content (1B).

### Example 2

A second series of polymerization runs are conducted following the procedures outlined in Example 1. The initial monomer feed to the reactor contained only ethylene to produce the polyethylene A block, two side stream feeds are then added to make the B block. A final feed is introduced with a high ethylene content to produce a semi-crystalline EP segment at the end or tip of the B block. Reaction conditions for runs 2A and 2B are shown in Table 1. In example 2A, a higher initial ethylene feed rate is used than in Example 2B to give the polymer a higher molecular weight and a greater percentage of A block.

These polymers are characterized in a manner similar to the polymers produced in Example 1. The results of these analyses are listed in Table 2. The semicrystalline end segment of the B block of Example 2A averaged 72.2 weight percent ethylene, while the semicrystalline end segment of the B block of Example 2B averaged 70 weight percent ethylene. DSC analysis of the polymers show that the polymers contain a semi-crystalline fraction melting at about 42° C. in addition to a polyethylene fraction which melts at 122° to 124° C. The moduli and tensile strength of the polymers for runs 2A and 2B are shown in Table 3.

### Example 3

In this example, a number of A B block polymers made by the procedure in Example 1 but over a broad range of reaction conditions, are tested for solubility in hexane at 22° C. The purpose of this testing is to determine how much B block is unconnected to an A block. The composition and molecular weight of the polymers vary widely. Solubility is determined by pressing 2.0 g of the block polymer onto a 20 mesh screen and immersing the polymer and screen in 200 cc of n-hexane. Wide-mouthed bottles are used and are occasionally swirled over a period of 3 to 5 days. The screen is removed and dried to constant weight in a vacuum oven to determine the amount of insoluble polymer. The hexane supernatant liquid is evaporated to dryness and the residue is weighed to measure the amount of soluble polymer. The sum of the two fractions showed 100% of the starting polymer is accounted for.

TABLE 1

| EXAMPLE | | | |
|---|---|---|---|
| 1A | 1B | 2A | 2B |

Main Flow g/h

| | | | | |
|---|---|---|---|---|
| hexane | 53803 | 53803 | 53803 | 53803 |
| propylene | 0 | 0 | 0 | 0 |
| ethylene | 151 | 124 | 151 | 73 |
| ENB | 0 | 0 | 0 | 0 |
| VC14 | 1.8 | 1.5 | 2.4 | 2.4 |
| A1/V mol/mol | 8 | 8 | 8 | 8 |

SIDE STREAM 1, g/h

| | | | | |
|---|---|---|---|---|
| hexane | 8910 | 8910 | 8910 | 8910 |
| propylene | 1228 | 1354 | 1125 | 1125 |
| ethylene | 110 | 148 | 122 | 122 |

SIDE STREAM 2, g/h

| | | | | |
|---|---|---|---|---|
| hexane | 6138 | 6138 | 5910 | 5910 |
| propylene | 358 | 509 | 413 | 413 |
| ethylene | 85 | 110 | 130 | 130 |

SIDE STREAM 3, g/h

| | | | | |
|---|---|---|---|---|
| hexane | 6217 | 6217 | 7920 | 7920 |
| propylene | 347 | 405 | 510 | 510 |
| ethylene | 80 | 108 | 255 | 255 |

TEMPERATURE, ° C.

| | | | | |
|---|---|---|---|---|
| feed | 20 | 20 | 19 | 19 |
| reactor outlet | 22 | 22 | 25 | 24 |

RESIDENCE TIME, min.

| | | | | |
|---|---|---|---|---|
| to side stream 1 | 0.024 | 0.024 | 0.024 | 0.024 |
| to side stream 2 | 0.064 | 0.064 | 0.109 | 0.109 |
| to side stream 3 | 0.10 | 0.10 | 0.147 | 0.147 |
| to side stream 4 | | | | |
| total | 0.139 | 0.139 | 0.183 | 0.183 |

PROCESS RESULTS

| | | | | |
|---|---|---|---|---|
| Wt % C₂ in polymer | 71.6 | 70.8 | 72.2 | 70.1 |
| Wt % ENB in polymer | 0 | 0 | 0 | 0 |
| Mooney (1 + 4, 150° C.) | 109 | 91.1 | 114 | 131 |
| Mw × 10−3 | 189 | 246 | 222 | 209 |
| Mn × 10−3 | 108 | 149 | 115 | 106 |
| Mw/Mn | 1.67 | 1.7 | 1.91 | 1.99 |
| Poly Rate, g/h | 387 | 368 | 689 | 597 |
| C2 = conv*, % | 65 | 54.8 | 75.6 | 72.2 |
| C3 = conv*, % | 5.7 | 4.4 | 9.4 | 8.7 |
| Cat eff, g poly/g VCL | 215 | 245.3 | 297 | 249 |

*conv—conversion

TABLE 2

| | EXAMPLE | | | |
|---|---|---|---|---|
| | 1A | 1B | 2A | 2B |
| Poly rate A block, g/hr | 151 | 124 | 151 | 73 |
| Poly rate B block, g/hr | 236 | 244 | 319 | 355 |
| Poly rate C block, g/hr | 0 | 0 | 259 | 265 |
| A block, wt % | 39.0 | 33.7 | 20.7 | 10.5 |
| B block, wt % | 61.0 | 66.3 | 43.7 | 51.2 |
| C block, wt % | 0 | 0 | 35.5 | 38.2 |
| Wt % C2 = in whole polymer | 71.6 | 72.9 | 72.2 | 70.1 |
| Wt % C2 = in B block | 53.4 | 59.1 | 59.0 | 63.9 |
| before final feed | | | | |
| Wt % C2 - in B block | | | 72.2 | 70.1 |
| after final feed | | | | |
| Wt % ENB whole polymer | | | | |
| Wt % ENB in EPDM segment | | | | |

GPC

| | | | | |
|---|---|---|---|---|
| Mw × 10−3 | 189 | 246 | 221 | 209 |
| Mn × 10−3 | 108 | 149 | 115 | 106 |
| Mw/Mn | 1.67 | 1.7 | 1.91 | 1.99 |

DSC heat of Fusion J/g Total Polymer

| | | | | |
|---|---|---|---|---|
| A block, J/g | 48 | 33 | 29.2 | 21.3 |
| B block, J/g | | 0.82 | 3.59 | 4.14 |
| Wt % soluble in n-hexane | | | 2.3 | 2.6 |

TABLE 3

| | EXAMPLE | | | |
|---|---|---|---|---|
| | 1A | 1B | 2A | 2B |
| 100% MODULUS, MPa | 2.4 | 2.3 | 2.7 | 2.2 |
| TENSILE STRENGTH | 3.5 | 9.7 | 15.4 | 5.4 |
| AT BREAK, MPA | | | | |
| EXTENSION AT BREAK, % | 780 | 1220 | 1090 | 740 |

The following prophetic examples further illustrate the invention. Unless otherwise indicated, all parts and percentages are by weight.

### Example A

A monolayer 15 mil thick protective film is made from a blend comprising 80 wt % of Example 1B, 20 wt % of a maleic anhydride (MAH) modified ethylene/1-octene copolymer (ENGAGE® 8400 polyethylene grafted at a level of about 1 wt % MAH, and having a post-modified MI of 1.25 g/10 min and a density of 0.87 g/cc), 1.5 wt % of Lupersol® 101, 0.8 wt % of tri-allyl cyanurate, 0.1 wt % of Chimassorb® 944, 0.2 wt % of Naugard® P, and 0.3 wt % of Cyasorb® UV 531. The melt temperature during film formation is kept below 120° C. to avoid premature crosslinking of the film during extrusion. This film is then used to prepare a solar cell module. The film is laminated at a temperature of 150° C. to a superstrate, e.g., a glass cover sheet, and the front surface of a solar cell, and then to the back surface of the solar cell and a backskin material, e.g., another glass cover sheet or any other substrate. The protective film is then subjected to conditions that will ensure that the film is substantially crosslinked.

### Example B

The procedure of Example A is repeated except that the blend comprised 90 wt % Example 1B and 10 wt % of a maleic anhydride (MAH) modified ethylene/1-octene (ENGAGE® 8400 polyethylene grafted at a level of 1 wt % MAH, and having a post-modified MI of 1.25 g/10 min and a density of 0.87 g/cc), and the melt temperature during film formation was kept below 120° C. to avoid premature crosslinking of the film during extrusion.

### Example C

The procedure of Example A is repeated except that the blend comprised 97 wt % Example 2A and 3 wt % of vinyl silane (no maleic anhydride modified ENGAGE® 8400 polyethylene), and the melt temperature during film formation was kept below 120° C. to avoid premature crosslinking of the film during extrusion.

### Test Methods and Results

The adhesion with glass is measured using silane-treated glass. The procedure of glass treatment is adapted it from a procedure in Gelest, Inc. “Silanes and Silicones, Catalog 3000 A”.

Approximately 10 mL of acetic acid is added to 200 mL of 95% ethanol in order to make the solution slightly acidic. Then, 4 mL of 3-aminopropyltrimethoxysilane is added with stirring, making a 2% solution of silane. The solution sits for 5 minutes to allow for hydrolysis to begin, and then it is transferred to a glass dish. Each plate is immersed in the solution for 2 minutes with gentle agitation, removed, rinsed briefly with 95% ethanol to remove excess silane, and allowed to drain. The plates are cured in an oven at 110° C. for 15 minutes. Then they are soaked in a 5% solution of sodium bicarbonate for 2 minutes in order to convert the acetate salt of the amine to the free amine. They are rinsed with water, wiped dry with a paper towel, and air dried at room temperature overnight.

The method for testing the adhesion strength between the polymer and glass is the 180° peel test. This is not an ASTM standard test, but it is used to examine the adhesion with glass for PV modules. The test sample is prepared by placing uncured film on the top of the glass, and then curing the film under pressure in a compression molding machine. The molded sample is held under laboratory conditions for two days before the test. The adhesion strength is measured with an Instron machine. The loading rate is 2 in/min, and the test is run under ambient conditions. The test is stopped after a stable peel region is observed (about 2 inches). The ratio of peel load over film width is reported as the adhesion strength.

Several important mechanical properties of the cured films are evaluated using tensile and dynamic mechanical analysis (DMA) methods. The tensile test is run under ambient conditions with a load rate of 2 in/min. The DMA method is conducted from −100 to 120° C.

The optical properties are determined as follows: Percent of light transmittance is measured by UV-vis spectroscopy. It measures the absorbance in the wavelength of 250 nm to 1200 nm. The internal haze is measured using ASTM D1003-61.

The results are reported in Table 4. The EVA is a fully formulated film available from ETIMEX.

TABLE 4
Test Results

| Key Properties | EVA |
|---|---|
| Elongation to break (%) | 411.7 |
| STDV* | 17.5 |
| Tensile strength at 85° C. (psi) | 51.2 |
| STDV* | 8.9 |
| Elongation to break at 85° C. (%) | 77.1 |
| STDV* | 16.3 |
| Adhesion with glass (N/mm) | 7 |
| % of transmittance | >97 |
| STDV* | 0.1 |
| Internal Haze | 2.8 |
| STDV* | 0.4 |

*STDV=Standard Deviation.

### Example D

### Copolymer Polyethylene-Based Encapsulant Film

Example 2B is used in this example. Several additives are selected to add functionality or improve the long term stability of the resin. They are UV absorbent Cyasorb UV 531, UV-stabilizer Chimassorb 944 LD, antioxidant Tinuvin 622 LD, vinyltrimethoxysilane (VTMS), and peroxide Luperox-101. The formulation in weight percent is described in Table 5.

TABLE 5
Film Formulation

| Formulation | Weight Percent |
|---|---|
| Example 2B | 97.34 |
| Cyasorb UV 531 | 0.3 |
| Chimassorb 944 LD | 0.1 |
| Tinuvin 622 LD | 0.1 |
| Irganox-168 | 0.08 |
| Silane (Dow Corning Z-6300) | 2 |
| Luperox-101 | 0.08 |
| Total | 100 |

### Sample Preparation

Example 2B pellets are dried at 40° C. for overnight in a dryer. The pellets and the additives are dry mixed and placed in a drum and tumbled for 30 minutes. Then the silane and peroxide are poured into the drum and tumbled for another 15 minutes. The well-mixed materials are fed to a film extruder for film casting.

Film is cast on a film line (single screw extruder, 24-inch width sheet die) and the processing conditions are summarized in Table 6.

TABLE 6
Process Conditions

| | | | Extruder Die | | | | | | |
|---|---|---|---|---|---|---|---|---|---|
| | | | Head P | Zone 1 | Zone 2 | Zone 3 | Adapter | Adapter | Die |
| Sample # | RPM | Amp | (psi) | (F.) | (F.) | (F.) | (F.) | (C.) | (C.) |
| 1 | 25 | 22 | 2,940 | 300 | 325 | 350 | 350 | 182 | 140 |

An 18-19 mil thick film is saved at 5.3 feet per minute (ft/min). The film sample is sealed in an aluminum bag to avoid UV-irradiation and moisture.

### Test Methods and Results

### Optical Property

The light transmittance of the film is examined by UV-visible spectrometer (Perkin Elmer UV-Vis 950 with scanning double monochromator and integrating sphere accessory). The samples used for this analysis have a thickness of 15 mils. The films show above 90% of transmittance over the wavelength range from 400 to 1100 nm.

### Adhesion to Glass

The method used for the adhesion test is a 180° peel test. This is not an ASTM standard test, but has been used to examine the adhesion with glass for photovoltaic module and auto laminate glass applications. The test sample is prepared by placing the film on the top of glass under pressure in a compression molding machine. The desired adhesion width is 1.0 inch. The frame used to hold the sample is 5 inches by 5 inches. A TEFLON™ sheet is placed between the glass and the material to separate the glass and polymer for the purpose of test setup. The conditions for the glass/film sample preparation are:
(1) 160° C. for 3 minutes at 80 pounds per square inch (psi) (2000 lbs),
(2) 160° C. for 30 minutes at 320 psi (8000 lbs),
(3) Cool to room temperature at 320 psi (8000 lbs), and
(4) Remove the sample from the chase and allow 48 hours for the material to condition at room temperature before the adhesion test.

The adhesion strength is measured with a materials testing system (Instron 5581). The loading rate is 2 inches/minutes and the tests are run at ambient conditions (24° C. and 50% relative humidity (RH)). A stable peel region is needed (about 2 inches) to evaluate the adhesion to glass. The ratio of peel load in the stable peel region over the film width is reported as the adhesion strength.

The effect of temperature and moisture on adhesion strength is examined using samples aged in hot water (80° C.) for one week. These samples are molded on glass, and then immersed in hot water for one week. These samples are then dried under laboratory conditions for two days before the adhesion test. In comparison, the adhesion strength of the same commercial EVA film as described above is also evaluated under the same conditions. The adhesion strength of the commercial sample is shown in Table 7.

TABLE 7
Tests Results of Adhesion to Glass

| | | | Adhesion |
|---|---|---|---|
| | Conditions for | Aging | Strength |
| Sample Information | Molding on Glass | Condition | (N/mm) |
| Commercial Film | 160° C., one hr | none | 10 |
| (cured) | | | |
| Commercial Film | 160° C., one hr | 80° C. in water | 1 |
| (cured) | | for one week | |

### Water Vapor Transmission Rate (WVTR)

The water vapor transmission rate is measured using a permeation analysis instrument (MOCON PERMATRAN W Model 101 K). All WVTR units are in grams per square meter per day (g/(m²-day) measured at 38° C. and 50° C. and 100% RH, an average of two specimens. The commercial EVA film as described above is also tested to compare the moisture barrier properties. The commercial film thickness is 15 mils, and the film is cured at 160° C. for 30 minutes. The results of WVTR testing are reported in Table 8.

TABLE 8
Summary of WVTR Test Results

| | | | | | Permeation | Permeation |
|---|---|---|---|---|---|---|
| | | | | | at 38 C. (g- | at 50 C. (g- |
| | | WVTR at 38 C. | WVTR at 50 C. | Thick | mil)/(m²- | mil)/(m²- |
| Film | Specimen | g/(m²-day) | g/(m²-day) | (mil) mil | day) | day) |
| Commercial | A | 44.52 | 98.74 | 16.80 | 737 | 1660 |
| Film | B | 44.54 | 99.14 | 16.60 | 749 | 1641 |
| | avg. | 44.53 | 98.94 | 16.70 | 743 | 1650 |

### Example E

Two set of samples are prepared to demonstrate that UV absorption can be shifted by using different UV-stabilizers. Example 1B polyolefin is used, and Table 9 reports the formulations with different UV-stabilizers (all amounts are in weight percent). The samples are made using a mixer at a temperature of 190° C. for 5 minutes. Thin films with a thickness of 16 mils are made using a compressing molding machine. The molding conditions are 10 minutes at 160° C., and then cooling to 24° C. in 30 minutes. The UV spectrum is measured using a UV/Vis spectrometer such as a Lambda 950. The results show that different types (and/or combinations) of UV-stabilizers can allow the absorption of UV radiation at a wavelength below 360 nm.

TABLE 9
Example 1B with Different UV-Stabilizers

| | | Absorber | Cyasorb | Cyasorb | Chimassorb | Chimassorb | Tinuvin |
|---|---|---|---|---|---|---|---|
| Sample | Example 1 | UV-531 | UV2908 | UV3529 | UV-119 | 944-LD | 622-LD |
| 1 | 100 | | | | | | |
| 2 | 99.7 | 0.3 | | | | | |
| 3 | 99.7 | | 0.3 | | | | |
| 4 | 99.7 | | | 0.3 | | | |
| 5 | 99.7 | | | | 0.3 | | |
| 6 | 99.5 | | | | | 0.25 | 0.25 |
| 7 | 99.85 | 0.15 | | | | | |

Another set of samples are prepared to examine UV-stability. Example 1A is selected for this study. Table 10 reports the formulations designed for encapsulant polymers for photovoltaic modules with different UV-stabilizers, silane and peroxide, and antioxidant. These formulations are designed to lower the UV absorbance and at the same time maintain and improved the long term UV-stability.

TABLE 10
Example 1A with Different UV-Stabilizers, Silanes, Peroxides and Antioxidants

| | | Absorber | Cyasorb | Cyasorb | | Doverphos | | Chimassorb | Chimassorb | Tinuvin | | |
|---|---|---|---|---|---|---|---|---|---|---|---|---|
| | Example | UV | UV | UV | Univil | S- | Hostavin | UV | 944 | 622 | Western | Irgafos |
| Samples | 1A | 531 | 2908 | 3529 | 4050 | 9228 | N30 | 119 | LD | LD | 399 | 166 |
| C 1 | 99.8 | | | | | | | | | | 0.2 | |
| C 2 | 99.3 | 0.3 | | | | | | | 0.1 | 0.1 | 0.2 | |
| C 3 | 99.5 | 0.3 | | | | | | | 0.1 | 0.1 | | |
| 1 | 99.5 | | 0.5 | | | | | | | | | |
| 2 | 99.5 | | | 0.5 | | | | | | | | |
| 3 | 99.5 | | | | | | | 0.5 | | | | |
| 4 | 99.5 | | | | | | | | 0.5 | | | |
| 5 | 99.7 | | | 0.3 | | | | | | 0.5 | | |
| 6 | 99.3 | | | 0.7 | | | | | | | | |
| 7 | 99.5 | | | | 0.5 | | | | | | | |
| 8 | 99.5 | | | | | | 0.5 | | | | | |
| 9 | 99.4 | 0.3 | | | | 0.1 | | | 0.1 | 0.1 | | |
| 10 | 99.3 | 0.3 | | | | | | | 0.1 | 0.1 | | 0.2 |
| 11 | 99.3 | | | 0.5 | | | | | | | | 0.2 |

Although the invention has been described in considerable detail through the preceding description and examples, this detail is for the purpose of illustration and is not to be construed as a limitation on the scope of the invention as it is described in the appended claims. All references, specifically including all United States patents, published patent applications and allowed patent applications, identified above are incorporated herein by reference for purposes of U.S. patent examination practice.

1. An electronic device module comprising:
A. At least one electronic device; and
B. a polymeric material in intimate contact with at least one surface of the electronic device, the polymeric material comprising a block copolymer comprising:
(1) A block,
(2) B block,
wherein said A block comprises ethylene; and said B block includes a first polymer segment and a tip segment each of said first polymer segment and said tip segment comprising at least 5 weight percent of the B block said first polymer segment being contiguous to a junction of said A block and said B block said first segment comprising ethylene and an alpha-olefin; said tip segment being further from said junction, said tip segment being a polymer of ethylene, and an alpha-olefin having an ethylene content of at least 60 mole percent based on the total moles of the monomers of said tip segment, the ethylene content of said tip segment being at least 5 mole percent greater than the ethylene content of said first portion;
(3) Optionally a vinyl silane in an amount of at least 0.1 wt % based on the weight of the copolymer;
(4) Optionally a free radical initiator or a photoinitiator in an amount of at least 0.05 wt % based on the weight of the copolymer; and
(5) Optionally a co-agent in an amount of at least 0.05 wt % based on the weight of the copolymer.

2. The electronic device module of claim 1 in which the A block consists of ethylene and from 0.03 to 2 mole percent of a non-conjugated diene, based on total moles of monomer in said block copolymer.

3. The module of claim 1 in which the electronic device is a solar cell.

4. The module of claim 1 in which at least one of the vinyl silane, free radical initiator and coagent is present.

5. The module of claim 4 in which the vinyl silane is vinyl tri-ethoxy silane or vinyl tri-methoxy silane, and the free radical initiator is a peroxide.

6. The module of claim 1 in which the polymeric material is in the form of a monolayer film in intimate contact with at least one face surface of the electronic device.

7. The module of claim 1 in which the polymeric material further comprises a scorch inhibitor in an amount from 0.01 to 1.7 wt %.

8. The module of claim 1 further comprising at least one glass cover sheet.

9. The module of claim 4 in which the free radical initiator is a photoinitiator.

10. The module of claim 1 in which the polymeric material further comprises a polyolefin polymer grafted with an unsaturated organic compound containing at least one ethylenic unsaturation and at least one carbonyl group.

11. The module of claim 10 in which the unsaturated organic compound is maleic anhydride.

12. The module of claim 10 in which the polyolefin copolymer is crosslinked such that the copolymer contains less than 85 percent xylene soluble extractables as measured by ASTM 2765-95.

13. The module of claim 12 in which the unsaturated organic compound is maleic anhydride.

14. A method of manufacturing an electronic device module, the method comprising the step of contacting at least one surface of an electronic device with a polymeric material comprising an ethylene-based block copolymer having an A block and a B block characterized by a nodular polymer formed by coupling two or more block copolymers.

15. The method of claim 14 in which the nodular polymer contains a coupling agent.
